(19) United States
(12) Patent Application Publication
(10) Pub. No.: US 2011/0117479 A1
(43) Pub. Date: May 19, 2011

(54) REFLECTIVE EXPOSURE MASK, METHOD OF MANUFACTURING REFLECTIVE EXPOSURE MASK, AND METHOD OF MANUFACTURING SEMICONDUCTOR DEVICE

(75) Inventors: Osamu SUGA, Kanagawa (JP); Takashi KAMO, Yokohama-shi (JP)

(73) Assignee: RENESAS ELECTRONICS CORPORATION, Kanagawa (JP)

(21) Appl. No.: 12/916,804

(22) Filed: Nov. 1, 2010

(30) Foreign Application Priority Data
Nov. 19, 2009 (JP) 2009-264177

(51) Int. Cl. G03F 1/00; G03F 7/20

(52) U.S. Cl. 430/5; 430/312

(57) ABSTRACT

A reflective exposure mask, a method of manufacturing the reflective exposure mask, and a method of manufacturing a semiconductor device for improving yield in an EUVL (extreme-ultraviolet lithography) using a reflective exposure mask formed to a reflective exposure mask blank are provided. A reflective exposure mask for EUVL includes a low-reflectivity conductor film, a multilayer reflecting film, and an absorber formed on a mask substrate in sequence. The low-reflectivity conductor film has a reflectivity lower than reflectivities of the multilayer reflecting film and the absorber. The absorber forms an absorber pattern in a pattern region of the mask substrate. The multilayer reflecting film has a light-shielding band formed by being removed in a portion surrounding an outer periphery of the pattern region in a groove-like shape. The low-reflectivity conductor film is exposed at a bottom portion of the light-shielding band in a groove-like shape.

### CROSS-REFERENCE TO RELATED APPLICATION

The present application claims priority from Japanese Patent Application No. 2009-264177 filed on Nov. 19, 2009, the content of which is hereby incorporated by reference into this application.

### TECHNICAL FIELD OF THE INVENTION

The present invention relates to a reflective exposure mask, a method of manufacturing the reflective exposure mask, and a method of manufacturing a semiconductor device. More particularly, the present invention relates to photolithography technology which uses extreme ultra violet (EUV) rays.

### BACKGROUND OF THE INVENTION

Semiconductor devices are formed by repeatedly using photolithography technology which irradiates exposure light to a mask on which a circuit pattern is patterned to transfer the circuit pattern to a semiconductor substrate (semiconductor wafer) through a demagnifying optical system.

In recent years, miniaturization (scaling) for improving performance of semiconductor devices has been advanced and technology for improving resolution by further shortening wavelengths of exposure light used in photolithography has been studied. For example, while there is ArF lithography using argon fluoride (ArF) excimer laser light having a wavelength of 193 nm, development of EUV lithography (EUVL) using EUV light having a wavelength of 13 .5 nm which is smaller than that of ArF excimer light is being advanced.

Normal photolithography technology uses a configuration in which a pattern formed on a mask is transferred onto a semiconductor substrate by making exposure light transmit through the mask to which a circuit pattern is formed. That is, the mask is formed of a material which is transmissive to the exposure light, and a desired circuit pattern is formed by forming a light-shielding pattern to the transmissive material.

However, since exposure light such as the EUV light having a short wavelength is prone to be absorbed by material and it is difficult to configure a transmissive optical system, a reflective exposure mask and a reflective optical system are generally used. Note that, while a wavelength range of the EUV light is defined to be 9 to 15 nm, when using the EUV light for lithography, a wavelength of 13.5 is mainly used. However, the wavelength is not limited to this, and wavelengths of 9.5 nm and so forth have been studied, and the EUV light is applicable to lithography as long as its wavelength is within the above-mentioned range (9 to 15 nm).

For example, International Application WO01/02908 (Patent Document 1) discloses technique of a photomask using a resist material, the technique disposing a transparent conductive film formed of a metal or organic matter to a lower portion or upper portion of a resist. Patent Document 1 mentions that a degradation of the patterning accuracy caused by a charge-up upon pattern delineation (patterning) can be reduced in this manner.

Also, for example, Japanese Patent Application Laid-Open Publication No. 2001-313248 (Patent Document 2) discloses technique of adding boron (B) to a silicon layer in a multilayered reflecting film in which molybdenum (Mo) layers and silicon (Si) layers are alternately stacked. Patent Document 2 mentions that, by improving conductivity of the multilayered reflecting film without largely lowering reflectivity of the multilayered reflecting film in this manner, a charge-up upon pattern delineation can be suppressed.

In addition, for example, Japanese Patent Application Laid-Open Publication No. 2007-194406 (Patent Document 3) discloses technique of a multilayer-film reflecting mirror formed by forming a multilayer film on a substrate, the technique disposing a conductive film, which is extended until a holding portion of the multilayer-film reflecting mirror, between a substrate and the multilayer film. Patent Document 3 mentions that grounding the multilayer film and applying potential to the multilayer film are possible in this manner without degrading optical performance after adjustment.

Further, for example, Japanese Patent Application Laid-Open Publication No. 2007-013149 (Patent Document 4) discloses technique of a reflective mask for a lithography apparatus using EUV, the technique disposing a conductor covering a part of the mask, being connected to a ground, and being contacted with a conductive coating formed of a metal-based compound. Patent Document 4 mentions that a problem of occurrence of particles caused by scratching on the conductive coating upon grounding a surface of the mask can be suppressed in this manner.

Still further, for example, T. Kamo et al., “EUVL practical mask structure with light shield area for 32 nm half pitch and beyond”, Proceedings of SPIE, Vol. 7122, 712227-1 to -11 (2008) (Non-patent Document 1) mentions that a problem of a change of an exposure pattern from a size of a single exposure shot can be solved by using a structure in which an absorber in an absorber region being away from a pattern boundary of a reflective exposure mask and a multilayer film are removed in EUV lithography technology.

Moreover, for example, M. Amemiya et al., “Experimental study of particle-free mask handling”, Proceedings of SPIE, Vol., 7271, 72713G-1 to -11 (2009) (Non-patent Document 2) mentions that the possibility of attachment of charged particles to a mask is raised when charging on the mask is significant, resulting in an increase of defects upon wafer transfer, and it may be a cause of a yield reduction.

### SUMMARY OF THE INVENTION

According to a study regarding EUVL technology by the inventors of the present invention, the following has been revealed.

A reflective exposure mask for EUVL studied by the present inventors has a structure in which a reflecting film is formed on a mask substrate and an absorber pattern of an absorber is formed on the reflecting film. The reflecting film has a high reflectivity to EUV light and the absorber has a low reflectivity to EUV light. Thus, a portion on the mask substrate to which the absorber is not formed and the reflecting film is exposed is a bright section. Meanwhile, EUV light is absorbed at a portion in which the absorber is formed, creating a dark section in EUV reflected light. In this manner, the reflective exposure mask generates a pattern, which is formed of bright sections and dark sections reflecting the absorber pattern on the mask substrate, as reflected EUV light.

As the reflective exposure mask for EUVL, it is necessary to generate a high contrast of a transferred image by EUV light. That is, the larger a reflectivity of the reflecting film and that of the absorber are, the more preferable it is. According to such a request, an approach of lowering the reflectivity to EUV light of the absorber has been made. Here, in view of the configuration of the reflecting optical system, it is necessary to make an incidence of EUV light inclined at about 6 degrees with respect to the mask. Therefore, when a thickness of the absorber is large for lowering reflectivity, a transfer size difference (also called horizontal-vertical size difference) between a pattern along the incident light and a pattern in a perpendicular direction becomes large due to a shadowing effect.

To such a problem, it is effective to use a half-tone phase shift mask structure. That is, by using a phase shift mask structure, it is possible to improve the contrast of bright sections and dark sections of the reflected light without thickening the absorber too much. Therefore, as well as suppressing the shadowing effect, it is possible to improve the transfer image contrast.

However, even when a reduction of the shadowing effect and an improvement of the transfer image contrast are achieved by using the phase shift mask structure, it has been known that a new problem as follows arises. More specifically, when the reflectivity from the absorber pattern is large, flare occurs due to leaked light from an adjacent shot, resulting in a lowering of an exposure margin. In other words, when the reflectivity of the absorber pattern is large as the absorber is thinned, reflected light of the absorber pattern becomes leaked light at a boundary portion of masks even when the reflectivity is in a range not problematic for the contrast of transfer image, and a non-exposed portion is eventually exposed.

To the problem, as disclosed in Patent Document 1 etc. mentioned above, there is effective technique of removing the absorber at a portion away from a boundary of an area in which the absorber pattern is formed and the reflecting film under the absorber pattern from the reflective exposure mask. By using such a structure, average reflectivity to EUV exposure light at the portion away from the boundary of the region in which the absorber pattern is formed can be suppressed to less than 0.5%. In this manner, leaked light occurring from an adjacent shot upon wafer exposure can be suppressed, and a change of an exposure pattern size due to the leaked light can be suppressed. As described above, a region of a reflective exposure mask in which an absorber and a reflective film outside an absorber pattern region are removed is called “light-shielding band.”

However, according to a further study by the inventors of the present invention, about the reflective exposure mask for EUVL to which the light-shielding band is provided, the following problems have been found out.

As described above, the light-shielding band is a region where an absorber and a reflecting film under the absorber outside a region in which an absorber pattern is formed are removed. In other words, the region, in which the absorber pattern for generating reflected light reflecting a desired pattern is formed, is surrounded by the light-shielding band and arranged inside the light-shielding band. That is, the absorber and the reflecting film in the region in which the absorber pattern is formed are isolated from the absorber and the reflecting film in the other region over the light-shielding band.

Meanwhile, in the reflective exposure mask for EUVL which the inventors of the present invention have been studied, the reflecting film and the absorber have conductivity, and an insulating material is used for the mask substrate. Therefore, in the structure having the light-shielding band as described above, the pattern region inside the light-shielding band is in a state of being electrically insulated (floating state) over the light-shielding band on the insulating mask substrate. When an EUV exposure is continued in the state, charges generated due to the photoelectric effect by an EUV light irradiation to the mask cannot escape outside the pattern region, and thus the pattern region gradually takes charges. When the charging of the mask becomes significant, a possibility of attachment of charged particles to the mask is raised. The particles generated in such a course become a cause of an increase of defects upon wafer transfer and a yield reduction. This is a problem revealed through a study of introducing a reflective exposure mask having a light-shielding band in which a reflecting film is dug as the inventors have studied about practical use of the EUVL.

Accordingly, a preferred aim of the present invention is to provide technology of improving yield in the EUVL which uses a reflective exposure mask formed to a reflective exposure mask blank.

The above and other preferred aims and novel characteristics of the present invention will be apparent from the description of the present specification and the accompanying drawings.

While a plurality of inventions are disclosed in the present application, a summary of one of the embodiments will be briefly described as follows.

A reflective exposure mask which reflects ultraviolet rays to supply the same as exposure light, the reflective exposure mask including: a mask substrate; a conductive film formed to cover an entire surface of a main surface of the mask substrate; a reflecting film disposed on the mask substrate via the conductive film and in contact with the conductive film; a light-shielding band that is a portion where the reflecting film is removed in a groove-like shape; and an absorber disposed on the reflecting film. Here, a reflectivity to extreme ultraviolet rays of the absorber is lower than a reflectivity to extreme ultraviolet rays of the reflecting film. In addition, the absorber in a pattern region on the mask substrate has an absorber pattern having a part covering the reflecting film and a part not covering the reflecting film to expose the reflecting film. Further, the pattern region is arranged inside an outer periphery of the mask substrate when viewing on a plane of the main surface of the mask substrate and also arranged at a position not to contact with the outer periphery of the mask substrate. Moreover, the light-shielding band is a portion outside an outer periphery of the pattern region when viewing on a plane of the main surface of the mask substrate and also a portion formed by removing the reflecting film in a groove-like shape to surround the pattern region and in a state in contact with the outer periphery of the pattern region. The conductive film is exposed at a bottom portion of the light-shielding band. Further, a reflectivity of the conductive film to extreme ultraviolet rays is lower than that of the reflecting film and the absorber to extreme ultraviolet rays.

A typical effect obtained by the above-described embodiment among the plurality of inventions disclosed in the present application will be briefly described as follows.

That is, yield can be improved in the EUVL using a reflective exposure mask formed to a reflective exposure mask blank.

### BRIEF DESCRIPTIONS OF THE DRAWINGS

FIG. 1 is a cross-sectional view of a reflective exposure mask according to a first embodiment of the present invention, the cross-sectional view being viewed in a direction of the arrow along the line A1-A1 in a plan view illustrated in FIG. 2;

FIG. 2 is a plan view of the reflective exposure mask according to the first embodiment of the present invention;

FIG. 3 is a cross-sectional view of the reflective exposure mask according to the first embodiment of the present invention in a manufacturing process, the cross-sectional view being viewed in the direction of the arrow along the line A1-A1 in FIG. 2;

FIG. 4 is a cross-sectional view of the reflective exposure mask in the manufacturing process continued from FIG. 3;

FIG. 5 is a cross-sectional view of the reflective exposure mask in the manufacturing process continued from FIG. 4;

FIG. 6 is a cross-sectional view of the reflective exposure mask in the manufacturing process continued from FIG. 5;

FIG. 7 is a cross-sectional view of the reflective exposure mask in the manufacturing process continued from FIG. 6;

FIG. 8 is a cross-sectional view of the reflective exposure mask in the manufacturing process continued from FIG. 7;

FIG. 9 is a cross-sectional view of the reflective exposure mask in the manufacturing process continued from FIG. 8;

FIG. 10 is a cross-sectional view of the reflective exposure mask in the manufacturing process continued from FIG. 9;

FIG. 11 is an explanatory diagram describing a manufacturing process of a semiconductor device according to a second embodiment of the present invention;

FIG. 12 is a plan view of a reflective exposure mask used in the manufacturing process of the semiconductor device according to the second embodiment of the present invention;

FIG. 13 is another explanatory diagram describing the manufacturing process of the semiconductor device according to the second embodiment of the present invention;

FIG. 14 is still another explanatory diagram describing the manufacturing process of the semiconductor device according to the second embodiment of the present invention;

FIG. 15 is still another explanatory diagram describing the manufacturing process of the semiconductor device according to the second embodiment of the present invention;

FIG. 16 is a cross-sectional view of another reflective exposure mask used in the manufacturing process of the semiconductor device according to the second embodiment of the present invention, the cross-sectional view being viewed in a direction of the arrow along the line A2-A2 in a plan view of FIG. 17;

FIG. 17 is a plan view of the another reflective exposure mask used in the manufacturing process of the semiconductor device according to the second embodiment of the present invention;

FIG. 18 is a cross-sectional view of a still another reflective exposure mask used in the manufacturing process of the semiconductor device according to the second embodiment of the present invention, the cross-sectional view being viewed in a direction of the arrow along the line A3-A3 in a plan view of FIG. 19;

FIG. 19 is a plan view of the still another reflective exposure mask used in the manufacturing process of the semiconductor device according to the second embodiment of the present invention;

FIG. 20 is a cross-sectional view of a reflective exposure mask which the inventors of the present invention have studied, the cross-sectional view being viewed in a direction of the arrow along the line Aa-Aa in a plan view of FIG. 21;

FIG. 21 is a plan view of the reflective exposure mask which the inventors of the present invention have studied;

FIG. 22 is an explanatory diagram describing the reflective exposure mask which the inventors of the present invention have studied;

FIG. 23 is an explanatory diagram describing a manufacturing process of a semiconductor device using the reflective exposure mask which the inventors of the present invention have studied;

FIG. 24 is another explanatory diagram describing the manufacturing process of the semiconductor device using the reflective exposure mask which the inventors of the present invention have studied;

FIG. 25 is a still another explanatory diagram describing the manufacturing process of the semiconductor device using the reflective exposure mask which the inventors of the present invention have studied;

FIG. 26 is an explanatory diagram describing another reflective exposure mask which the inventors of the present invention have studied;

FIG. 27 is an explanatory diagram describing a manufacturing process of a semiconductor device using the another reflective exposure mask which the inventors of the present invention have studied;

FIG. 28 is a cross-sectional view of the reflective exposure mask illustrated in FIG. 26; and

FIG. 29 is a cross-sectional view of another reflective exposure mask illustrated in FIG. 26.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like) , the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate or similar shapes and the like are included therein unless otherwise stated or except the case where it is conceivable that they are apparently excluded in principle. The same goes for the numerical value and the range mentioned above. Also, components having the same function are denoted by the same reference symbols throughout the drawings for describing the embodiments, and the repetitive description thereof is omitted. Hereinafter, embodiments of the present invention will be described in detail with reference to the accompanying drawings.

### First Embodiment

First, problems having been found in a reflective exposure mask having a structure which the inventors of the present invention have studied and a method of manufacturing a semiconductor device using the reflective exposure mask will be described in detail with reference to the accompanying drawings.

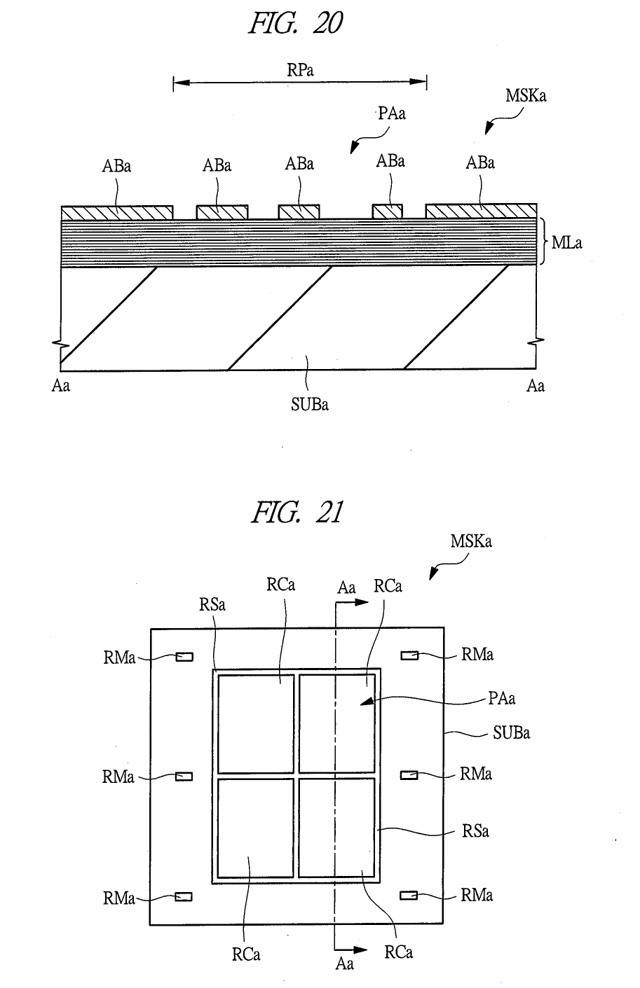

With reference to FIGS. 20 and 21, a structure of a reflective exposure mask MSKa which the inventors of the present invention have previously studied will be described. FIG. 20 is a cross-sectional view of the reflective exposure mask which the present inventors have studied, the cross-sectional view being viewed along a direction of the arrow along the line Aa-Aa in the plan view of FIG. 21.

The reflective exposure mask MSKa which the present inventors have previously studied includes a reflecting film MLa formed on a mask substrate SUBa, and an absorber ABa disposed on the reflecting film MLa. The reflecting film MLa is a film which reflects EUV light, and the absorber ABa is a film which absorbs EUV light. Since EUV light is absorbed by the absorber ABa, a reflectivity of the absorber ABa is low.

The absorber ABa includes some portions removed in a pattern region RPa on the mask substrate SUBa. In this manner, in the pattern region RPa of the mask substrate SUBa, an absorber pattern PAa is formed including a portion where the absorber ABa is arranged and a portion where the reflecting film MLa is exposed when viewing the substrate in a plane.

The pattern region RPa in which the absorber pattern PAa is arranged includes chip regions RCa and a scribe region RSa. The chip region RCa includes an absorber pattern PAa for exposing a region for forming a chip on a semiconductor wafer, and the scribe region RSa includes an absorber pattern PAa for exposing scribe lines on the semiconductor wafer. Also, in a periphery of the pattern region RPa, mark regions RMa including marks for mask alignment and/or wafer alignment marks are provided.

At the reflective exposure mask MSKa which the present inventors have studied, reflective light generated from EUV light irradiated to the pattern region RPa having the absorber pattern

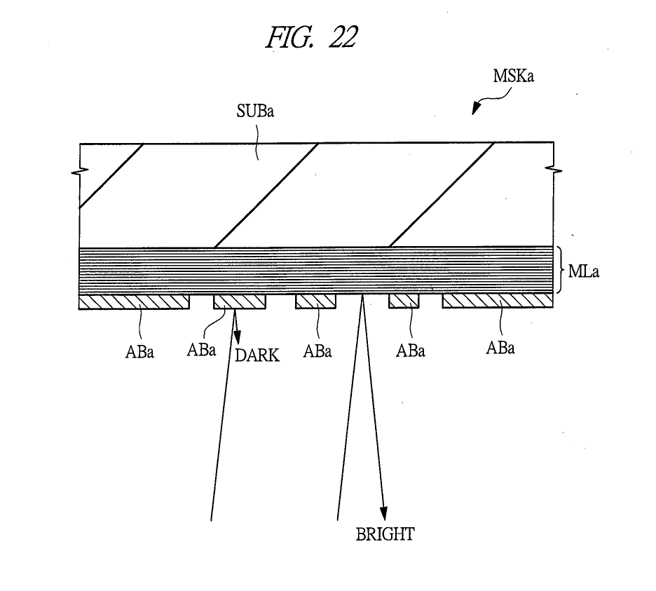

PAa is demagnified and projected so that an EUV resist film on the semiconductor wafer is exposed. As illustrated in FIG. 22, most of the incident EUV light to the absorber ABa of the reflective exposure mask MSKa is absorbed so that dark sections in the reflective light are generated, and the incident EUV light to the reflecting film MLa is reflected at a high reflectivity so that bright sections in the reflected light are generated. At the reflective exposure mask MSKa which the present inventors have previously studied, in this manner, EUV reflected light having a bright and dark pattern reflecting the absorber pattern PAa formed in the pattern region RPa can be obtained.

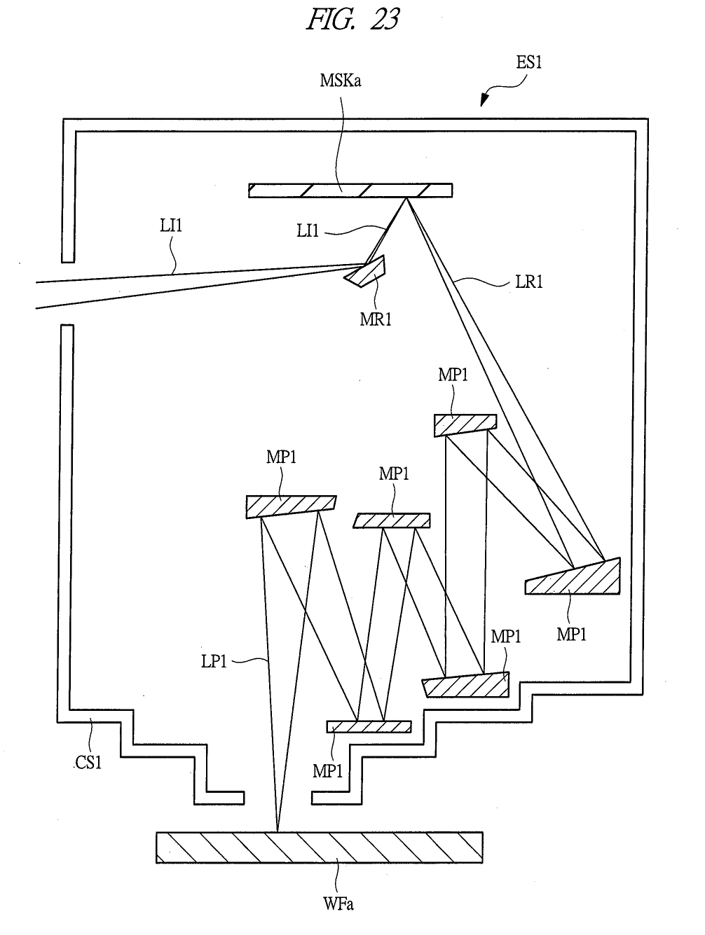

FIG. 23 illustrates an explanatory diagram describing an exposure process for exposing the EUV resist film (not illustrated) on a semiconductor wafer WFa using the reflective exposure mask MSKa described above. Particularly, FIG. 23 illustrates an explanatory diagram of an EUV exposure apparatus ES1 . The EUV exposure apparatus ES1 includes a reflection optical system MR1, the reflective exposure mask MSKa, an optical system box CS1, and a reflection projection optical system MP1.

A direction of incident EUV light LI1 came from an EUV light source is changed by the reflection optical system MR1 and irradiated to the pattern region RPa (see FIGS. 20 and 21 described above) of the reflective exposure mask MSKa. The incident EUV light LI1 irradiated to the reflective exposure mask MSKa becomes reflected EUV light LR1 reflecting the absorber pattern PAa (see FIGS. 20 and 21 described above) , and further becomes demagnified projected EUV light LP1 via the reflection projection optical system MP1 formed of a plurality of multilayer mirrors and is irradiated to the semiconductor wafer WFa. By the EUV exposure, an image of the absorber pattern PAa is produced on the semiconductor wafer WFa.

The exposure optical system including the reflection optical system MR1, the reflective exposure mask MSKa and the reflection projection optical system MP1 is surrounded by an optical system box CS1, and an inside of the optical system box CS1 is exhausted to vacuum to have a degree of vacuum higher than that of a periphery of the optical system box CS1. It is for avoiding absorption and attenuation (decay) of short-wavelength light of 13.5 nm wavelength in the air. In addition, the optical system box CS1 on the semiconductor wafer WFa side is opened. The configuration of the optical system has a structure in which a center axis is shifted for preventing a mechanical vignetting by a reflecting lens. This structure is aimed at obtaining a wide exposure field while everything in the structure is configured by reflection optical system. Therefore, the incident EUV light LI1 is irradiated at an incident angle of 5 to 10 degrees with respect to the reflective exposure mask MSKa, and an image is produced by the demagnified projected EUV light LP1 also inclined with respect to the semiconductor wafer WFa.

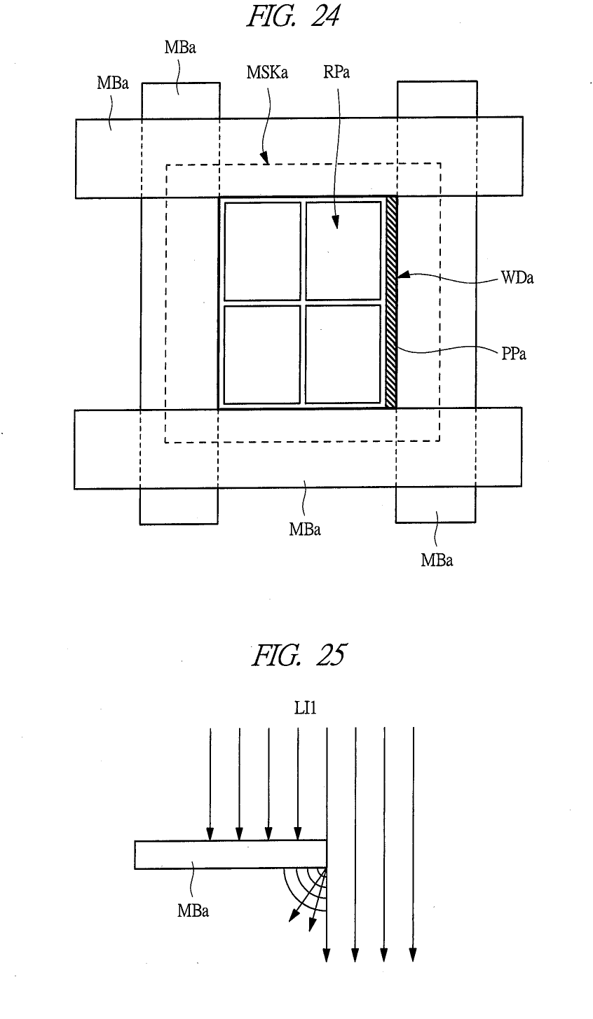

Here, in the EUV exposure, it is necessary to obtain the reflected EUV light LR1 reflecting the absorber pattern PAa (see FIGS. 20 and 21 described above) by irradiating the incident EUV light LI1 only to the pattern region RPa (see FIGS. 20 and 21 described above) of the reflective exposure mask MSKa. Thus, upon irradiating the incident EUV light LI1 to the reflective exposure mask MSKa, a masking blade MBa is used as illustrated in FIG. 24. That is, the incident EUV light is irradiated in a state in which the masking blade MBa is arranged to shield a portion other than the pattern region RPa of the reflective exposure mask MSKa. In this manner, the incident EUV light LI1 can be irradiated to the pattern region RPa of the reflective exposure mask MSKa, thereby obtaining the reflected EUV light reflecting the absorber pattern PAa. One pair of the masking blades MBa is provided in each of an X direction and a Y direction, and each of the pairs are movable in a one-dimensional direction above a mask surface, and thus the pattern region RPa having a desired size can be provided regardless of a type of the mask.

Meanwhile, since it is difficult to accurately stop the masking blade MBa, which is mechanically operated, so that only the portion of the pattern region RPa of the reflective exposure mask MSKa is exposed, there is a possibility that a portion other than the pattern region RPa may also be exposed. In other words, it is difficult to accurately align an opening window WDa of the masking blade MBa and the pattern region RPa of the reflective exposure mask MSKa, and thus a non-exposed region PPa of the reflective exposure mask is exposed to the opening window WDa.

Further, even if the masking blade MBa can be accurately stopped, as illustrated in FIG. 25, the incident EUV light LI1 is diffracted at an edge portion of the masking blade MBa, and thus a perfect light shielding is difficult to achieve.

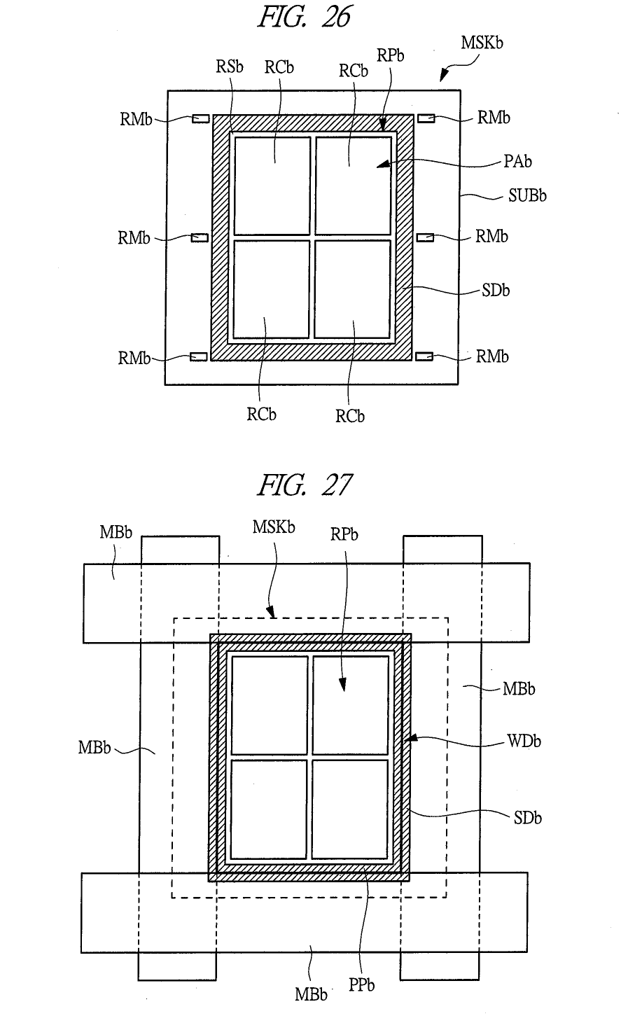

As to this problem, the present inventors have studied about technology of providing a light-shielding band SDb to a reflective exposure mask MSKb as illustrated in FIG. 26. A configuration of the reflective exposure mask MSKb is the same as that of the reflective exposure mask MSKa described above with reference to FIGS. 20 and 21 other than the point of providing the light-shielding band SDb.

The light-shielding band SDb is a region in which a material having a low reflectivity with respect to the incident EUV light LI1 (see FIG. 23 described above) is arranged to surround an outer periphery portion of the pattern region RPb in the reflective exposure mask MSKb. That is, when the incident EUV light LI1 is irradiated to the light-shielding band SDb, reflected light is not generated from the region. In this manner, as illustrated in FIG. 27, it is not necessary to align the masking blade MBb with the pattern region RPb, and it may be sufficient if at least an edge portion of the masking blade MBb is stopped in a range of the light-shielding band SDb. The reason is, even if the non-exposed portion PPb other than the pattern region RPb is exposed from the opening window WDb of the masking blade MBb, reflected light is not generated when the non-exposed portion PPb is the light-shielding band SDb, and unwilling exposure of other regions by leaked light due to the reflected light may not occur.

As such a configuration of the light-shielding band SDb, the present inventors have studied about the reflective exposure mask MSKb as described below.

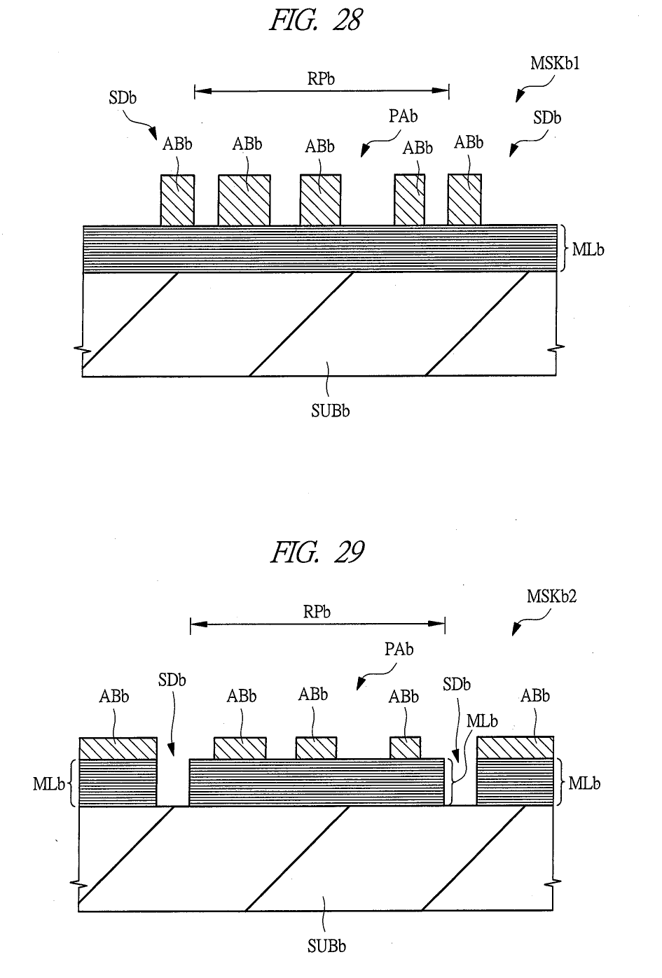

First, as illustrated in FIG. 28, a reflective exposure mask MSKb1 in which the light-shielding band SDb is formed of a material same as the absorber ABb forming the absorber pattern PAb of the pattern region RPb has been studied. Since a material having a low reflectivity with respect to EUV light is used for the absorber ABb as describe above, the absorber ABb is used as the light-shielding band SDb in the structure. Note that, the intention to provide the light-shielding band SDb to the reflective exposure mask MSKb1 is to cut leaked light in a periphery of the pattern, and it is not sufficient only by obtaining a contrast to a reflecting portion as the absorber ABb of the pattern region pattern region RPb do. In other words, the material of the light-shielding band SDb is necessary to have a further lower reflectivity to EUV light than that of the absorber ABb of the pattern region RPb. Therefore, the present inventors have studied about a structure in which the absorber ABb as the light-shielding band SDb is thickened. The thicker the absorber ABb, the lower the reflectivity of the absorber ABb, and thus, an absorber having a low reflectivity desired as the light-shielding band SDb can be formed.

Here, in a process of forming the reflective exposure mask MSKb1 which the present inventors have studied, an absorber film to be the absorber ABb is formed on a reflecting film MLb, and the absorber film is processed so that the absorber pattern PAb and the light-shielding band SDb are integrally formed. Thus, to thickly form the absorber ABb as the light-shielding band SDb, it is also necessary to thickly form the absorber ABb of the absorber pattern PAID. However, as described with reference to FIG. 23 above, in an EUV exposure method by a reflection projection optical system, it is necessary to irradiate the incident EUV light LI1 inclined with respect to the mask. Thus, when the absorber pattern PAb is thickly formed such as the reflective exposure mask MSKb1, it becomes easier to invite occurrence of a dimension misalignment of an exposure pattern due to the shadowing effect.

To avoid the problem, the present inventors have studied about a method of forming the absorber ABb as the absorber pattern PAb and the absorber ABb as the light-shielding band SDb in separate processes so that each of the absorbers ABb has a suitable thickness. However, it has been made clear that it is unrealistic in view of an increase of the number of manufacturing processes (particularly, the number of lithography processes to process the absorber film) and reliability.

Meanwhile, as illustrated in FIG. 29, the present inventors have studied about a reflective exposure mask MSKb2 having a structure in which the absorber ABb and the reflecting film MLb are removed in an outer periphery portion of the pattern region RPb, and the outer periphery portion of the pattern region RPb in which the absorber ABb and the reflecting film MLb are removed is taken as the light-shielding band SDb. Quartz (silica) glass or a low thermal expansion material has a very low reflectivity to EUV light. Accordingly, the reflecting film MLb is removed in the light-shielding band SDb region, and the reflective exposure mask MSKb2 including that part as the light-shielding band SDb has been studied. The present inventors have confirmed that, according to the structure, the reflective exposure mask MSKb2 having a structure having desired functions as the light-shielding band SDb can be achieved.

However, also in the reflective exposure mask MSKb2 in which the light-shielding band SDb is formed by digging the reflecting film MLb and exposing the mask substrate SUBb in this manner, it has been made clear that the problems as described below are posed according to a further study by the present inventors.

The reflective exposure mask MSKb2 is fixed by electrostatic attraction when being mounted to the EUV exposure apparatus ES1 as illustrated in FIG. 23. Such a fixing method is also called ESC (electrostatic chuck) method. It has been known that, when the reflective exposure mask MSKb2 is fixed by the ESC method, the reflective exposure mask MSKb2 is charged. In addition, it has been also known that, in the situation that exposure light having a short wavelength and high energy as EUV light is irradiated, charges are generated by the photoelectric effect, and thus the reflective exposure mask MSKb2 is charged.

Normally, to remove the charges generated in that way, the reflecting film MLb and/or the absorber ABb, which are conductive, in a region not related to the exposed pattern region RPb are conducted to a ground (earth) potential. Meanwhile, in the reflective exposure mask MSKb2 which the present inventors have studied, the reflecting film MLb and the absorber ABb of the pattern region RPb are isolated from the other region as separated by he light-shielding band SDb and the mask substrate SUBb, and thus the reflecting film MLb and the absorber ABb of the pattern region RPb are in an insulated state (floating state). In other words, even when the reflecting film MLb and/or the absorber ABb in the other region than the pattern region RPb are at a ground potential, the pattern region pattern region RPb which is electrically insulated cannot be discharged. In this manner, when using the reflective exposure mask MSKb2 of the structure in FIG. 29, by repeating EUV exposure processes, the pattern region RPb is gradually charged.

When the reflective exposure mask MSKb2 is in a charged state, it is prone to adsorb particles. As described with reference to FIG. 23, particularly, the inside of the optical system box CS1 is put at a high vacuum in the EUV apparatus ES1. However, according to the study by the present inventors, it has been revealed that, even in such a high vacuum, not negligible particles are adsorbed to the reflective exposure mask MSKb2 which is charged as mentioned above. Particularly, in the reflective exposure mask MSKb2 in FIG. 29 described above, it is an important problem as the pattern region pattern region RPb, which generates reflected light reflecting the absorber pattern PAID, is charged and becomes prone to adsorb charges. Because, for example, when the particles are contamination of carbon series which absorb EUV light, upon performing an EUV exposure in a state in which the particles are adsorbed, the reflectivity of the reflecting film MLb is lowered, and a dimension accuracy of a transferred pattern is lowered.

The problems as mentioned above have been revealed by the study of practical use of EUVL by the present inventors and the study of an introduction of the reflective exposure mask MSKb2 having the light-shielding band SDb of the aspect in which a reflecting film is dug.

Based on the foregoing, in a first embodiment, a structure and a method of manufacturing a reflective exposure mask for EUVL having a structure which includes a light-shielding band in a periphery of a pattern on a mask and charges are not prone to stored will be described. Technology of solving the problems mentioned above and improving yield in EUVL using a reflective exposure mask formed to a mask blank for reflective exposure by such a reflective exposure mask is provided.

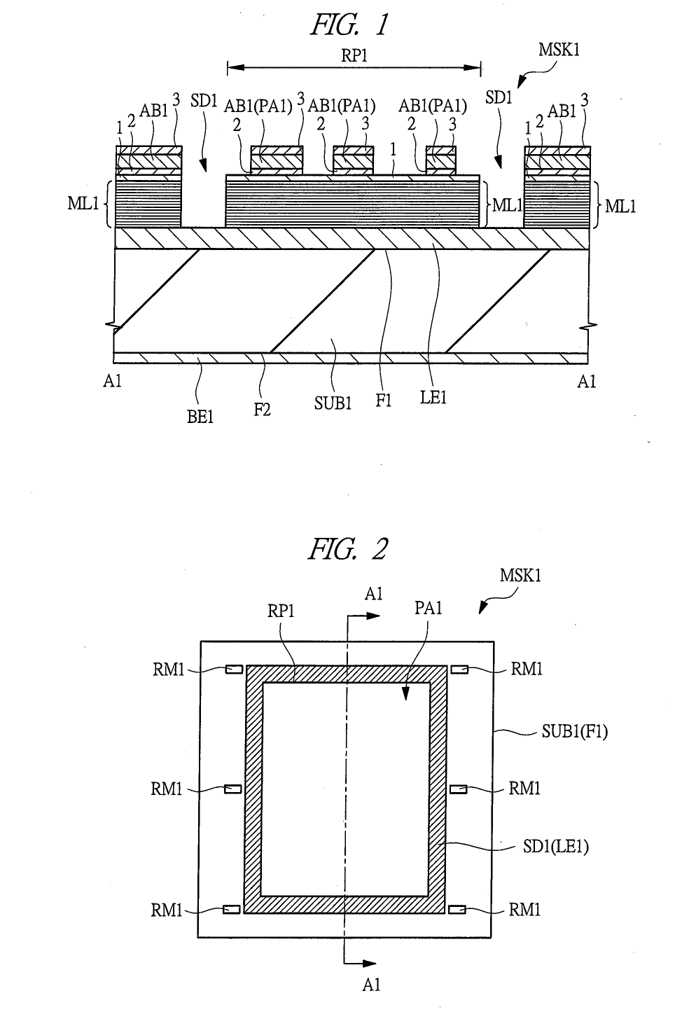

FIGS. 1 and 2 illustrate a cross-sectional view and a plan view describing a structure of a reflective exposure mask MSK1 of the first embodiment. FIG. 1 is a cross-sectional view of the reflective exposure mask MSK1 of the first embodiment, the cross-sectional view being viewed in a direction of the arrow along the line A1-A1 in the plan view of FIG. 2. Note that, while there is a portion to which hatching is added in FIG. 2 for the matter of convenience, there is no special meaning in view of the structure. Hereinafter, the same goes to hatchings added to plan views.

In the following, a detailed configuration of the reflective exposure mask MSK1 of the first embodiment will be described. The reflective exposure mask MSK1 of the first embodiment is used in EUVL reflecting the incident EUV light (ultraviolet rays) LI1 and demagnifying the same by the reflection projection optical system MP1, and supplying the same as the demagnified projected EUV light (exposure light) LP1 in the method of using the EUV exposure apparatus in FIG. 23 described above.

The reflective exposure mask MSK1 of the first embodiment is formed of the following components. Detailed configurations of each component will be described later.

A low reflectivity conductor film (conductor film) LE1 is formed on the mask substrate SUB1 to cover an entire surface of a main surface F1 of the mask substrate SUB1. Further, on the mask substrate SUB1, a multilayer reflecting film (reflecting film) ML1 is disposed via the low reflectivity conductor film LE1 and in contact with the low reflectivity conductor film LE1. The light-shielding band SD1, which is a part in which the multilayer reflecting film (reflecting film) ML1 is removed in a groove-like shape, is formed to the multilayer reflecting film ML1. The light-shielding band SD1 and a configuration in a periphery of the light-shielding band SD1 will be described in detail later. An absorber AB1 is disposed on the multilayer reflecting film ML1. The absorber AB1 includes an absorber pattern PA1 which is a planar pattern in a pattern region RP1 on the mask substrate SUB1. Configurations of the pattern region RP1 and the absorber pattern PA1 will be described in detail later. Also, a back-surface conductor film BE1 is formed to cover a back surface F2 positioned on an opposite side of the main surface F1 in a thickness direction of the mask substrate SUB1. The back-surface conductor film BE1 is a component for fixing the reflective exposure mask MSK1 by the ESC method, and formed of a conductor film mainly containing, for example, chrome or chrome nitride.

Note that a surface of the multilayer reflecting film ML1 may be covered by a protective layer 1 formed of , for example, ruthenium or silicon. A buffer layer 2 formed of, for example, chrome nitride (CrN) may be disposed between the absorber AB1 and the multilayer reflecting film ML1. A surface of the absorber AB1 may be covered by a low reflection layer 3 formed of, for example, tantalum boride (TaBO) or tantalum silicate (TaSiO) . Such a low reflection layer 3 has a low reflectivity to inspection light in a mask inspection. Moreover, in a periphery of the pattern region RP1 on the mask substrate SUB1, marks for mask position alignment and mark regions RM1 having a wafer alignment mark are provided.

Each component described above forming the reflective exposure mask MSK1 of the first embodiment has the following features.

The mask substrate SUB1 is formed of an insulator mainly containing quartz glass or a low temperature expansion material (LTEM) . Since EUV light absorbed by the absorber AB1 is mainly converted to thermal energy in an EUV exposure process, an insulator having a low coefficient of thermal expansion is suitable for the mask substrate SUB1.

Also, the low reflectivity conductor film LE1 is a film which absorbs EUV light, and also is a film having conductivity. Such a low reflectivity conductor film LE1 is formed of, for example, a conductor film mainly containing a metal-based compound. The metal-based compound forming the low reflectivity conductor film LE1 is, for example, tantalum boride nitride (TaBN) , tantalum silicide (TaSi) , tantalum nitride (TaN) , tantalum carbide nitride (TaCN) , tantalum carbide (TaC) , titanium carbide (TiC) , titanium nitride (TiN) , titanium carbide nitride (TiCN) , chrome nitride (CrN) , or aluminum nitride (AlN) . Here, the low reflectivity conductor film LE1 is formed of the same material as the absorber AB1. A reflectivity to EUV light of the low reflectivity conductor film LE1 is lower than a reflectivity to EUV light of the multilayer reflecting film ML1. Also, the reflectivity to EUV light of the low reflectivity conductor film LE1 is lower than a reflectivity to EUV light of the absorber AB1.

The multilayer reflecting film ML1 is a film which reflects EUV light. Such a multilayer reflecting film ML1 is formed of a multilayer film of 40 sets of layers of molybdenum (Mo) having about a 3-nm thickness and silicon (Si) having about a 4-nm thickness, the layers being alternately stacked. A component of EUV light to transmit through each film is reflected at interfaces, and magnified by interference phenomenon of a plurality of reflected light to each other. Thus, by forming the multilayer reflecting film ML1 by such a multilayer film, the reflectivity to EUV light can be increased. The reflectivity to EUV light of the multilayer reflecting film ML1 is higher than a reflectivity to EUV light of the low reflectivity conductor film LE1. Also, the reflectivity to EUV light of the multilayer reflecting film ML1 is higher than a reflectivity to EUV light of the absorber AB1.

The absorber AB1 is a film which absorbs EUV light. Such an absorber AB1 is formed of a film mainly containing a metal-based compound. Here, as described above, the absorber AB1 is formed of the same material as the low reflectivity conductor film LE1. That is, in the same manner as the low reflectivity conductor film LE1, the metal-based compound forming the absorber AB1 is, for example, tantalum boride nitride, tantalum silicide, tantalum nitride, tantalum carbide nitride, tantalum carbide, titanium carbide, titanium nitride, titanium carbide nitride, chrome nitride, or aluminum nitride. The reflectivity to EUV light of the absorber AB1 is lower than the reflectivity to EUV light of the multilayer reflecting film ML1.

The absorber pattern PA1 is a planar pattern which the absorber AB1 forms in the pattern region RP1 on the mask substrate SUB1 . The absorber AB1 in the pattern region RP1 on the mask substrate SUB1 forms an absorber pattern including a part covering the multilayer reflecting film ML1 and a part not covering the multilayer reflecting film ML1 to expose the multilayer reflecting film ML1. In other words, when viewing the main surface F1 of the mask substrate SUB1 facing the main surface F1, in the pattern region RP1, there are a region in which the absorber AB1 is arranged and a region in which the multilayer reflecting film ML1 is exposed, and these regions form the absorber pattern PA1 as a planar pattern.

The pattern region RP1 in which the absorber pattern PA1 is a region arranged on the mask substrate SUB1 is inside an outer periphery of the mask substrate SUB1 when viewing the plane of the main surface F1 of the mask substrate SUB1, and also is a region positioned not to be in contact with the outer periphery of the mask substrate SUB1.

In the reflective exposure mask MSK1 of the first embodiment, in the same manner as the descriptions with reference to FIG. 23, reflected light generated from the EUV light irradiated to the pattern region RP1 including the absorber pattern PA1 is demagnified and projected to expose an EUV resist film on a semiconductor substrate. Here, in the same manner as the descriptions with reference to FIG. 22, most of the incident EUV light to the absorber AB1 is absorbed, creating dark sections of the reflected light, and the incident EUV light to the multilayer reflecting film ML1 exposed from the absorber AB1 is reflected at a high reflectivity, forming bright sections of the reflected light. A method of irradiating the EUV light to the pattern region RP1 of the reflective exposure mask MSK1 is the same as the method described above with reference to FIG. 26 etc. In the reflective exposure mask MSK1, in this manner, reflected EUV light having bright and dark sections reflecting the absorber pattern PA1 formed to the pattern region RP1 can be generated. Also, as described above with reference to FIGS. 24 to 29, a structure including a light-shielding band (for example, the light-shielding band SDb in FIG. 26) is desired as the reflective exposure mask for EUVL (for example, the reflective exposure mask MSKb in FIG. 26) . The light-shielding band SD1 which the reflective exposure mask MSK1 of the first embodiment includes has the following structure.

The light-shielding band SD1 of the reflective exposure mask MSK1 of the first embodiment is a portion surrounding an outer periphery portion of the pattern region RP1 where the absorber AB1 and the multilayer reflecting film ML1 are removed. More specifically, when viewing on the plane of the main surface F1 of the mask substrate SUB1, the absorber AB1 and the multilayer reflecting film ML1 are removed in a groove-like shape in a portion surrounding the pattern region RP1 and in contact with the outer periphery of the pattern region RP1, thereby taking the portion as the light-shielding band SD1. This point is the same as the reflective exposure mask MSKb2 which the present inventors have previously studied.

In the reflective exposure mask MSK1 of the first embodiment, at a bottom portion of the light-shielding band SD1 which is a portion where the absorber AB1 and the multilayer reflecting film ML1 are removed in a groove-like shape, the low reflectivity conductor film LE1 is exposed. In other words, in the reflective exposure mask MSK1 of the first embodiment, as described above, the low reflectivity conductor film LE1 is arranged between the mask substrate SUB1 and the multilayer reflecting film ML1, and the low reflectivity conductor film LE1 covering the mask substrate SUB1 is exposed at the bottom portion of the light-shielding band SD1 where the multilayer reflecting film ML1 is removed in a groove-like shape. In the plan view of FIG. 2, the portion where the low reflectivity conductor film LE1 is exposed is illustrated with hatching. Hereinafter, the same goes to the hatching added in drawings of plan views of any reflective exposure mask.

As describe above, as the low reflectivity conductor film LE1, a material having a reflectivity to EUV light lower than that of the multilayer reflecting film ML1 and the absorber AB1 is used. Therefore, most of the EUV light incident to the region of the light-shielding band SD1 to be irradiated to the low reflectivity conductor film LE1 is not reflected, generating dark sections. In this manner, the light-shielding band SD1 of the reflective exposure mask MSK1 has a function as a light-shielding band in the same manner as the structure in which the mask substrate SUBb is exposed at the bottom portion as described above with reference to FIG. 29.

Further, in the reflective exposure mask MSK1 of the first embodiment, the multilayer reflecting film ML1 is disposed to be in contact with the low reflectivity conductor film LE1 having conductivity. In this manner, while the multilayer reflecting film ML1 including the absorber pattern PA1 in the pattern region RP1 is isolated in a plane by the groove-like light-shielding band SD1, since the multilayer reflecting film ML1 is in contact with the low reflectivity conductor film LE1 arranged at the bottom portion of the light-shielding band SD1, the multilayer reflecting film ML1 will not be in an electrically floating state. That is, the multilayer reflecting film ML1 in the pattern region RP1 is electrically conducted to the multilayer reflecting film ML1 and the absorber AB1 arranged in the other region than the pattern region RP1 via the low reflectivity conductor film LE1 at the bottom. This is because the low reflectivity conductor film LE1 arranged at a lower layer of the multilayer reflecting film ML1 is formed to cover the entire surface of the main surface F1 of the mask substrate SUB1 . Particularly, the low reflectivity conductor film LE1 is also formed in the other part of the pattern region RP1 of the mask substrate SUB1 . Therefore, by setting the low reflectivity conductor film LE1, the multilayer reflecting film ML1, or the absorber AB1 in the other region than the pattern region RP1 at a ground potential, the multilayer reflecting film ML1 in the pattern region RP1 can be set to a ground potential via the low reflectivity conductor film LEI. In this manner, even when charges are generated in the pattern region RP1 during the EUV exposure process due to the ESC for wafer fixing or the photoelectric effect, charges can be removed via the low reflectivity conductor film LE1. Therefore, adsorption of particles to the reflective exposure mask MSK1 etc. can be reduced. As a result, by using the reflective exposure mask MSK1 of the first embodiment, yield can be improved in the EUVL using a reflective exposure mask formed to a reflective exposure mask blank.

Here, in the same reason as described above with reference to FIG. 28, the smaller the leaked light by the reflection of the EUV light from the light-shielding band SD1 is, the more preferable it is. In other words, the smaller the reflectivity to EUV light of the low reflectivity conductor film LE1 exposed at the bottom portion of the light-shielding band SD1 is, the more preferable it is. Accordingly, in the reflective exposure mask MSK1 of the first embodiment, as described above, the low reflectivity conductor film LE1 having a reflectivity to EUV light lower than the multilayer reflecting film ML1 and the absorber AB1 is used.

To lower the reflectivity to EUV light of the low reflectivity conductor film LE1, it is effective to thicken the low reflectivity conductor film LE1. This is because the reflectivity can be reduced by increasing the absorbability of EUV light by thickening the low reflectivity conductor film LE1. That is, even when the absorber AB1 and the low reflectivity conductor film LE1 are formed of the same material as described above, the low reflectivity conductor film LE1 having a lower reflectivity than the absorber AB1 can be achieved by thickly forming the low reflectivity conductor film LE1. Here, in the reflective exposure mask MSK1 of the first embodiment, the absorber AB1 forming the absorber pattern PA1 and the low reflectivity conductor film LE1 are formed of different layers. Thus, the absorber AB1 and the low reflectivity conductor film LE1 are formed (deposited) in different processes and thus a thickness of the low reflectivity conductor film LE1 can be a desirable one regardless of a thickness of the absorber AB1. In other words, without thickening the absorber AB1 about which the shadowing effect is concerned, the reflectivity to EUV light can be lowered by thickening the low reflectivity conductor film LE1. In this manner, the reflected EUV light from the light-shielding band SD1 is further reduced, and thus influence from the leaked light from an adjacent shot in the EUVL can be reduced and an exposure margin can be improved. As a result, by using the reflective exposure mask MSK1 of the first embodiment, yield can be improved in an EUVL using a reflective exposure mask formed to a reflective exposure mask blank.

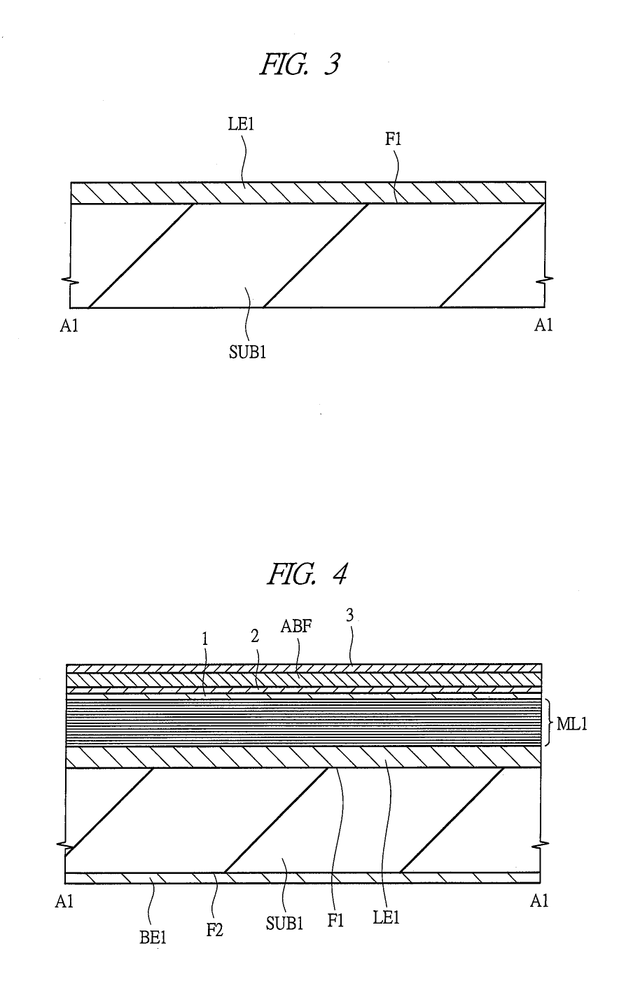

Hereinafter, a method of manufacturing the reflective exposure mask MSK1 of the first embodiment having the effects as described above will be described with reference to FIGS. 3 to 10. FIGS. 3 to 10 are cross-sectional views of the reflective exposure mask MSK1 according to the first embodiment during a manufacturing process, the cross-sectional views being viewed in a direction of the arrow along the portion corresponding to the line A1-A1 in FIG. 2. Note that material and shape of each component is the same as those described above with reference to FIGS. 1 and 2 unless otherwise particularly stated.

First, as illustrated in FIG. 3, the mask substrate SUB1 is prepared, and the low reflectivity conductor film LE1 is formed to cover the main surface F1 of the mask substrate SUB1 . Subsequently, as illustrated in FIG. 4, to cover the low reflectivity conductor film LEI, the multilayer reflecting film ML1, the protective layer 1, the buffer layer 2, the absorber film ABF, and the low reflection layer 3 are formed in series. Also, the back-surface conductor film BE1 is formed to the back surface F2 of the mask substrate SUB1. Here, as the multilayer reflecting film ML1, silicon and molybdenum are alternately stacked for about 40 sets of layers. Since the absorber film ABF is a film for forming the absorber pattern PA1 described above with reference to FIG. 1 by processing the absorber film ABF in a later step, a material forming the absorber AB1 is deposited as the absorber film ABF. Note that the mask substrate SUB1 in this state will be called a mask blank which means a mask to which a pattern is not formed.

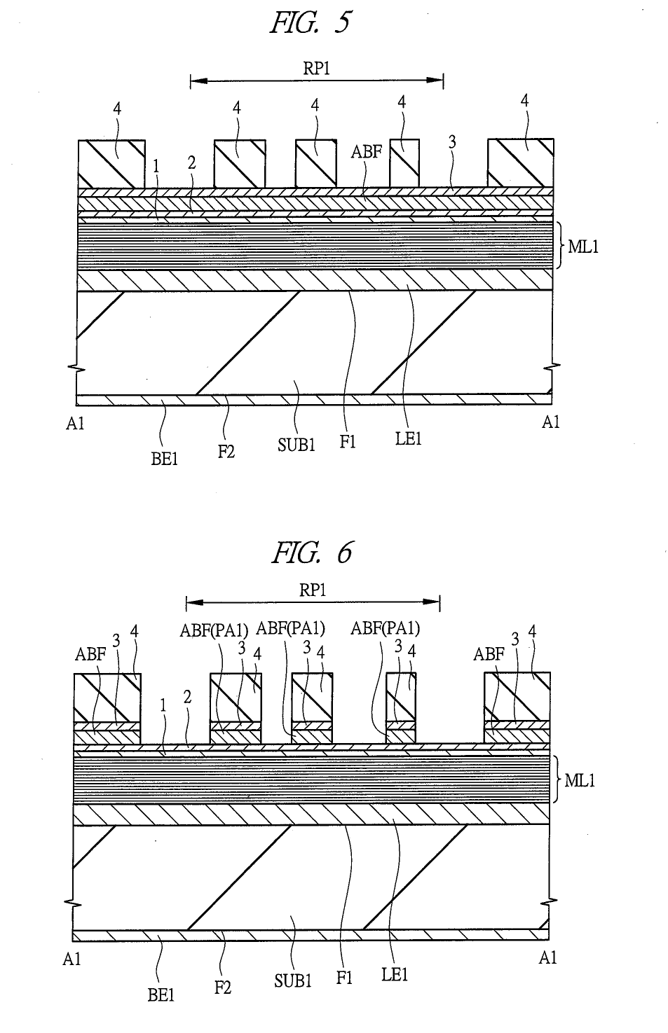

Next, as illustrated in FIG. 5, an electron beam resist film 4 for mask processing is applied on the low reflection layer 3 having a low reflectivity to inspection light in a mask inspection, and patterned by an electron bean (EB) patterning. The electron beam resist film 4 is formed as an etching mask for forming the absorber pattern PA1 by processing the absorber film ABF. Therefore, the electron beam resist film 4 is patterned to be a planar pattern same as the absorber pattern PA1. As described above with reference to FIG. 1, the absorber pattern PA1 is disposed in the pattern region RP1 of the mask substrate SUB1, and thus the planar pattern of the electron beam resist film 4 is also formed in the pattern region RP1.

Next, as illustrated in FIG. 6, using the electron beam resist film 4 as an etching mask, a part of the low reflection layer 3 exposed from the electron beam resist film 4 is etched, and the absorber film ABF is subsequently removed by etching. Here, the buffer layer 2 at the lower layer of the absorber film ABF is used as an etching stopper. In this manner, the absorber film ABF in the pattern region RP1 of the mask substrate SUB1 is processed, so that the absorber pattern PA1 including a part covering the multilayer reflecting film ML1 and a part not covering the multilayer reflecting film ML1 to expose the multilayer reflecting film ML1 is formed. Thereafter, the electron beam resist film 4 is removed.

Next, as illustrated in FIG. 7, using the low reflection layer 3 and the absorber film ABF processed as the absorber pattern PA1 as an etching mask, a part of the buffer layer 2 exposed from the etching mask is removed by etching.

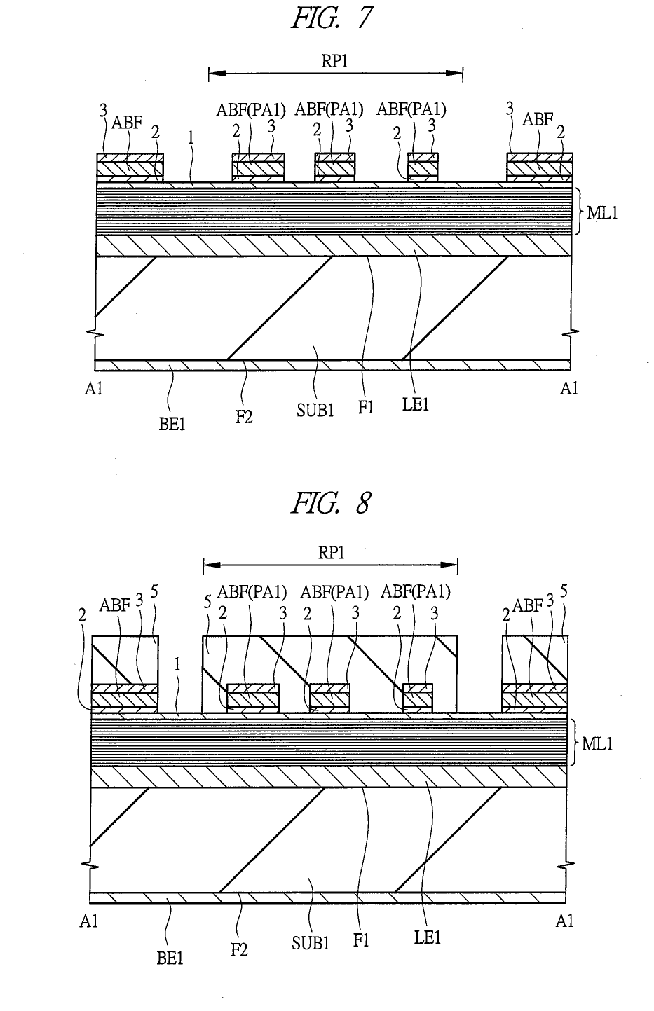

Next, as illustrated in FIG. 8, to cover the components described above, a photoresist film 5 is applied on the mask substrate SUB1 and patterned by a laser patterning. The photoresist film 5 is formed as an etching mask by processing the multilayer reflecting film ML1 for forming the light-shielding band SD1 described above with reference to FIG. 1. Therefore, the photoresist film 5 is patterned to have a shape as the light-shielding band SD1 in which a portion to remove the multilayer reflecting film ML1 is opened. Herein, an electron beam resist film may be used instead of the photoresist film 5. In this case, the electron beam resist film is patterned by an electron beam patterning instead of a laser patterning.

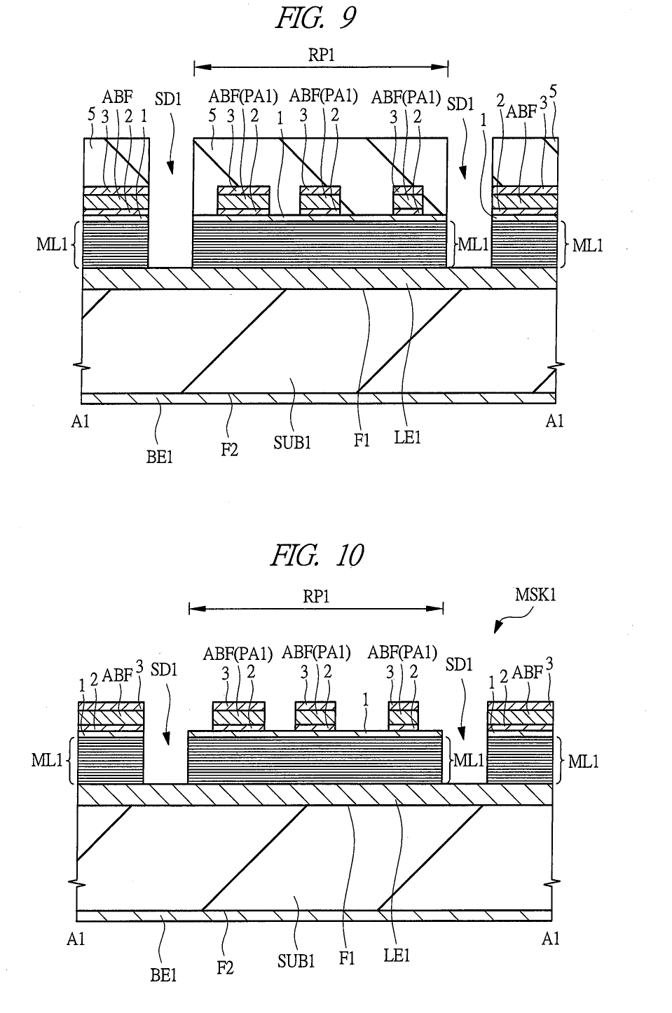

Next, as illustrated in FIG. 9, using the photoresist film 5 as an etching mask, an etching is performed on the protective layer 1 in a portion exposed from the photoresist film 5, and the multilayer reflecting film ML1 is subsequently removed by etching. In this manner, by removing a part of the multilayer reflecting film ML1 in a groove-like shape, the light-shielding band SD1 is formed. More detailed shape of the light-shielding band SD1 to be formed by removing the multilayer reflecting film ML1 is the same as that described above with reference to FIGS. 1 and 2. In this process, the low reflectivity conductor film LE1 arranged at the lower layer of the multilayer reflecting film ML1 and formed of a material different from that of the multilayer reflecting film ML1 is used as an etching stopper. That is, the low reflectivity conductor film LE1 is not removed in the etching of this process and thus the structure in which the low reflectivity conductor film LE1 is exposed at the bottom portion of the light-shielding band SD1 as described above with reference to FIG. 1 can be formed. Thereafter, the photoresist film 5 is removed, so that the reflective exposure mask MSK1 of the first embodiment as illustrated in FIG. 10 is completed.

As described above, in the process of manufacturing the reflective exposure mask MSK1 of the first embodiment, by adding a step of forming the low reflectivity conductor film LE1 first on the mask substrate SUB1, an effective reflective exposure mask MSK1 as described above with reference to FIGS. 1 and 2 can be formed. Here, as a processing of the low reflectivity conductor film LE1 is not necessary, it is not necessary to add a lithography process and a large change in the mask manufacturing process is not necessary. In addition, even when the low reflectivity conductor film LE1 is formed of the same material as that of the absorber film ABF, processes of forming the low reflectivity conductor film LE1 and the absorber film ABF are independent. Therefore, it is easy to achieve a configuration in which the low reflectivity conductor film LE1 is thicker than the absorber film ABF.

### Second Embodiment

In a second embodiment, a method of manufacturing a semiconductor device actually including a step of performing an EUV exposure using the reflective exposure mask MSK1 described in the first embodiment will be described.

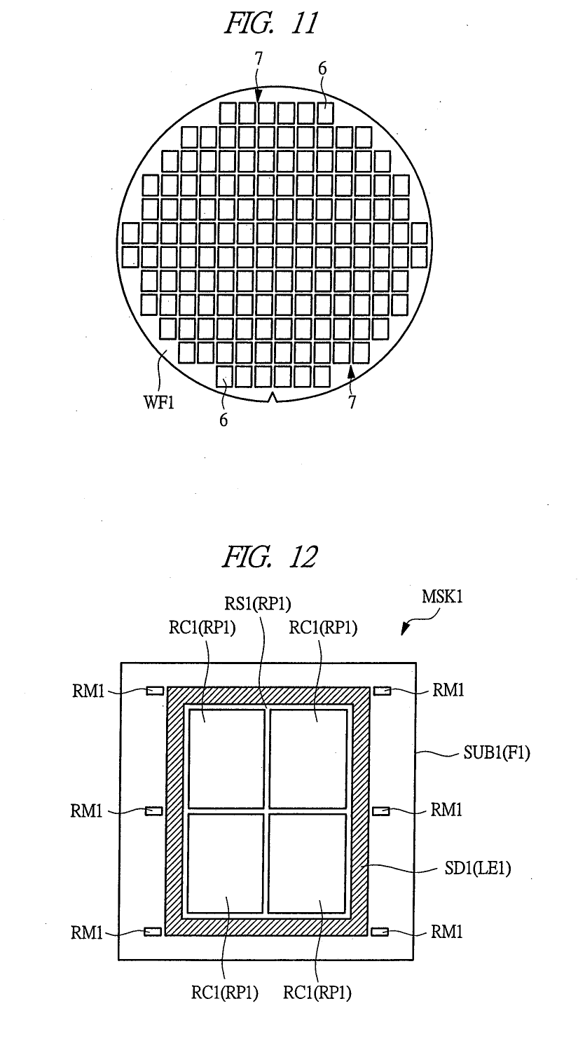

FIG. 11 illustrates an explanatory diagram of a semiconductor wafer WF1 used in the method of manufacturing a semiconductor device of the second embodiment. On the semiconductor wafer WF1, chip-forming regions 6 for forming semiconductor chips are aligned. In addition, the chip-forming regions 6 are mutually separated by scribe lines 7. In the method of manufacturing a semiconductor device, after forming desired circuits to the chip-forming regions 6 of the semiconductor wafer WF1, the scribe lines 7 are cut by a scriber, thereby making each of the chip-forming regions 6 into a chip piece. Note that checking of the process may be performed by inspecting electric characteristics during the manufacturing process of the semiconductor device by forming an element group for test (test element group: TEG) to the scribe lines 7.

FIG. 12 illustrates a plan view of the reflective exposure mask MSK1 used for transferring a desired pattern to each of the chip-forming regions 6 of the semiconductor wafer WF1 described above. In the method of manufacturing a semiconductor device of the second embodiment, first, such a reflective exposure mask MSK1 is prepared. the reflective exposure mask MSK1 has the following configuration in addition to the configuration described above with reference to FIGS. 1 and 2. More specifically, in the reflective exposure mask MSK1, the pattern region RP1, in which the absorber pattern PA1 is arranged, is formed of chip regions RC1 and a scribe region RS1. The chip regions RC1 and the scribe region RS1 have the absorber pattern PA1 for exposing the chip-forming regions 6 and the scribe lines 7 on the semiconductor wafer WF1 described above, respectively. In more detail, in the absorber pattern PA1 formed to the pattern region RP1 of the reflective exposure mask MSK1, a pattern to be projected to the chip-forming region 6 is arranged in the chip region RC1 and a pattern to be projected to the scribe lines 7 (for example, a TEG pattern) is arranged in the scribe region RS1. FIG. 12 illustrates a structure in which four chip regions RC1 separated by the scribe region RS1 are arranged in the reflective exposure mask MSK1. That is, four chip-forming regions 6 on the semiconductor wafer WF1 can be simultaneously exposed by such a reflective exposure mask MSK1.

On the semiconductor wafer WF1, an EUV resist film whose characteristic is changed by an exposure under EUV light is formed. By irradiating (exposing) demagnified and projected EUV light from the reflective exposure mask MSK1, the absorber pattern PA1 formed in the pattern region RP1 of the reflective exposure mask MSK1 is transferred. Here, in the same manner as that described above with reference to FIG. 23, EUV light (the incident EUV light LI1) is irradiated to the pattern region RP1, thereby obtaining reflected light (the reflected EUV light LR1) . Then, the reflected light is demagnified by the reflection projection optical system MP1 (the demagnified projected EUV light LP1) to expose the EUV resist film on the semiconductor wafer WF1.

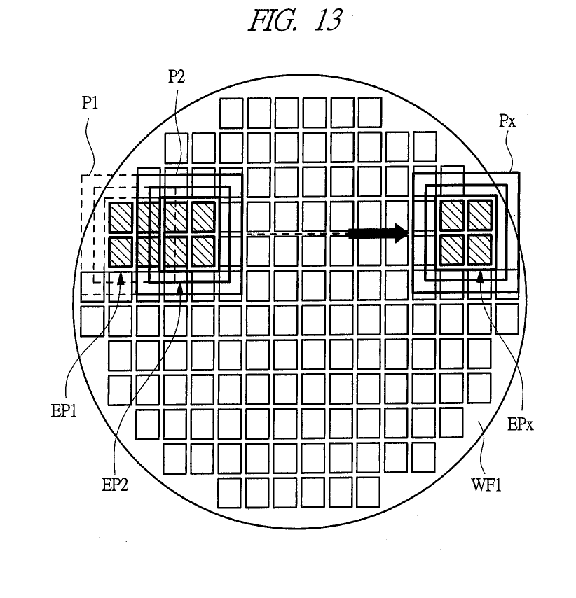

FIG. 13 illustrates an explanatory diagram for describing a situation of exposing each region (EP1, EP2, EPx) on the semiconductor wafer WF1. First, a projected pattern P1 of the reflective exposure mask MSK1 demagnified in the above-described manner is projected to a first region EP1 on the semiconductor wafer WF1, thereby exposing the EUV resist film in the first region EP1. Then, a wafer stage mounting the semiconductor wafer WF1 thereon is suitably moved in an x direction or a y direction. A projected pattern P2 of the reflective exposure mask MSK1 demagnified in the same manner as described above is projected to a second region EP2 adjacent to the first region EP1 on the semiconductor wafer WF1, thereby exposing the EUV resist film in the second region EP2. By repeating the steps, a projected pattern of the reflective exposure mask MSK1 is projected to the whole region including a region EPx etc. on the semiconductor wafer WF1, thereby exposing the EUV resist film on the semiconductor wafer WF1.

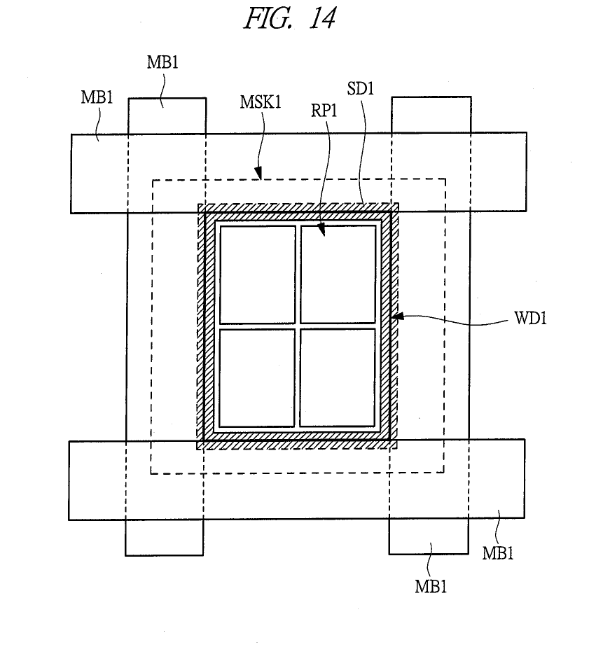

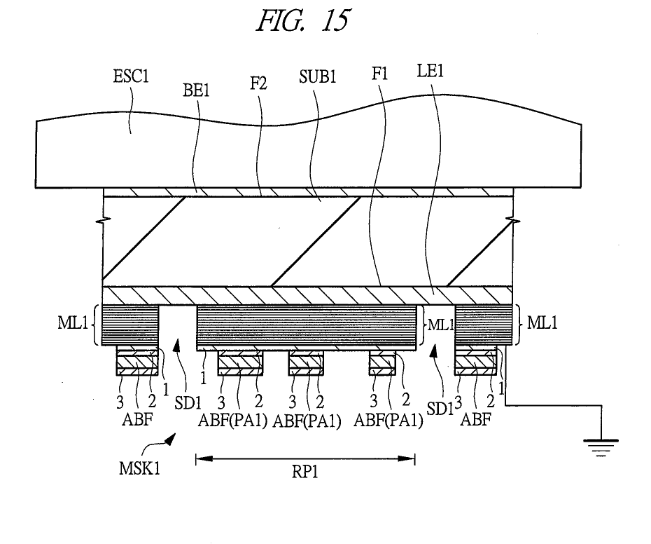

During the EUV exposure process described above, as illustrated in FIG. 14, the other region than the pattern region RP1 of the reflective exposure mask MSK1 is shielded by a masking blade MB1. In other words, EUV light is irradiated to the pattern region RP1 of the reflective exposure mask MSK1 being exposed from an opening window WD1 of the masking blade, so that EUV light having a bright and dark pattern reflecting the absorber pattern PA1 can be generated while shielding irradiation of the EUV light to the other region than the pattern region RP1.

More specifically, the masking blade MB1 which does not pass the EUV light is arranged to be overlapped with the other region than the pattern region RP1 in a plane in the reflective exposure mask MSK1. Here, in the mask substrate SUB1 of the reflective exposure mask MSK1, the masking blade MB1 is arranged in the manner described above on the main surface F1 side to which the absorber pattern PA1 is formed. Thereafter, to the reflective exposure mask MSK1, EUV light is irradiated from the side where the masking blade MB1 is disposed. In this manner, reflected light from the pattern region RP1 not being covered by the masking blade MB1 and being exposed from the opening window WD1 can be obtained.

The reflective exposure mask MSK1 of the second embodiment has the light-shielding band SD1 as described above. In this manner, without accurately coincide an outer periphery of the pattern region RP1 of the reflective exposure mask MSK1 and an edge of the masking blade MB1, influence of leaked light can be reduced. More specifically, as long as the edge portion of the masking blade MB1 is within the range of the light-shielding band SD1, i.e., as long as the edge portion of the masking blade MB1 is stopped at a position overlapped with the light-shielding band SD1 in a plane, leaked light from the other region than the pattern region RP1 of the reflective exposure mask MSK1 will not be generated. The reason is that, even when the other region than the pattern region RP1 is exposed from the opening window WD1, that exposed part is a part of the light-shielding band SD1 as long as the edge portion of the masking blade MB1 is stopped within the range of the light-shielding band SD1, and thus significant reflected light is difficult to be generated from the light-shielding band SDI. In this manner, by using the reflective exposure mask MSK1 including the light-shielding band SDI, it becomes difficult for unintended exposure due to leaked light to occur. As a result, by using the method of manufacturing a semiconductor device using the reflective exposure mask MSK1 according to the second embodiment, yield can be improved in the EUVL using a reflective exposure mask formed to a reflective exposure mask blank.

In addition, as illustrated in FIG. 15, in the method of manufacturing a semiconductor device according to the second embodiment, the reflective exposure mask MSK1 is fixed to an electrostatic chuck table ESC1 during the EUV exposure process. Here, the back-surface conductive film BE1 formed to the back surface F2 of the reflective exposure mask MSK1 is electrostatically chucked (ESC) so that the reflective exposure mask MSK1 is fixed.

When a reflective exposure mask is fixed to an electrostatic chuck table by the electrostatic chuck method, charges are generated to the reflective exposure mask. For example, in the reflective exposure mask MSKb2 which the present inventors have been previously studied as described above with reference to FIG. 29, the multilayer reflecting film MLb of the pattern region RPb is in an electrically floating state, and thus charges cannot escape and the pattern region RPb is charged. When the pattern region RPb is in a charged state, it becomes easier for particles to be adsorbed and a possibility of causing a size failure of a transferred pattern is increased. For example, when it is possible to contact to an external part to the pattern region RPb in an electrically floating state from an external part and set the region at a ground potential, the problem can be solved. However, it is difficult to provide the mechanism of contacting the pattern region RPb from an external part without influencing the transferred pattern. Also, even when the mask is fixed regardless of the electrostatic chuck method, due to photoelectric effect by EUV light, charges are generated to the pattern region RPb to which the EUV light is irradiated, causing the same problem.

Meanwhile, according to the method of manufacturing a semiconductor device according to the second embodiment, the main surface F1 of the mask substrate SUB1 in the reflective exposure mask MSK1 is covered by the low reflectivity conductor film LE1 having conductivity. The low reflectivity conductor film LE1 is formed to cover the entire of the main surface F1 of the mask substrate SUB1 regardless of the pattern region RP1. In other words, from a lower portion of the multilayer reflecting film ML1 of the pattern region RP1 to which charging is concerned to an outside of the pattern region RP1, the low reflectivity conductor film LE1 is integrally formed. Therefore, it is possible to electrically contact to the low reflectivity conductor film LE1 at a portion, which will not influence the transferred pattern, other than the pattern region RP1. And, by setting the low reflectivity conductor film LE1 to a ground potential, the multilayer reflecting film ML1 and the absorber pattern PA1 in the pattern region RP1 arranged to be in contact with the low reflectivity conductor film LE1 can be discharged. In this manner, in the EUVL, even when the reflective exposure mask MSK1 including the light-shielding band SD1 having a structure in which the multilayer reflecting film ML1 is dug is used, the pattern region RP1 can be discharged without influencing the transferred pattern, and it can be difficult for particles to be adsorbed. Therefore, a resolution failure or a lowering of size accuracy of the transferred pattern due to adsorption of particles can be prevented. As a result, by using the method of manufacturing a semiconductor device using the reflective exposure mask MSK1 according to the second embodiment, yield can be further improved in the EUVL using a reflective exposure mask.

Here, in FIG. 15 described above, as a method of electrically connecting to the low reflectivity conductor film LE1 at a portion other than the pattern region RP1, a structure of electrically connecting to the multilayer reflecting film ML1 formed on the low reflectivity conductor film LE1 outside the pattern region RP1 and the light-shielding band SD1 is illustrated. Note that an electric connection may be made to the absorber film ABF formed to a further upper layer of the multilayer reflecting film ML1.

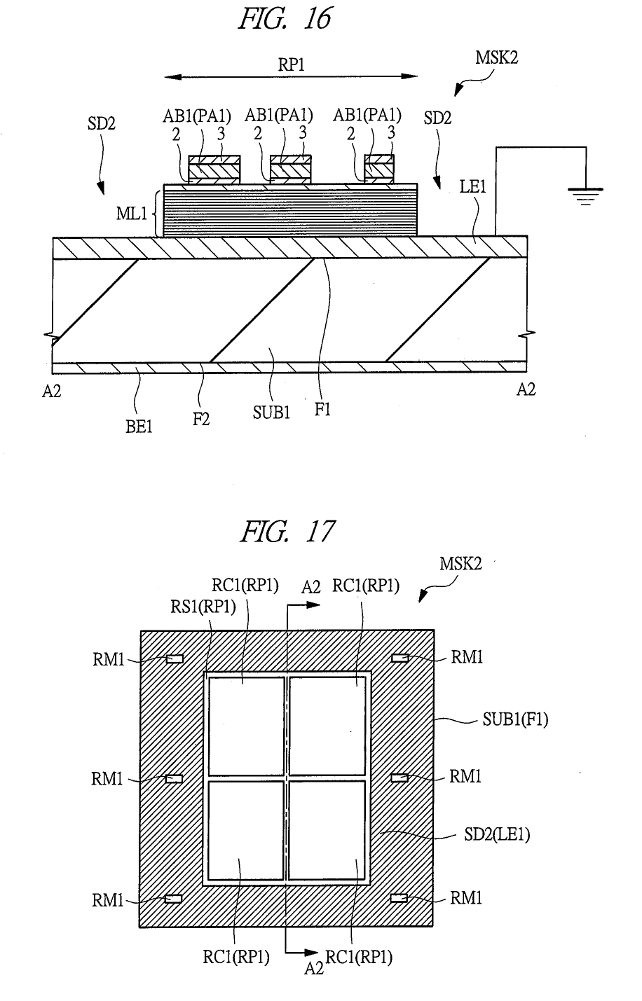

Further, in FIGS. 16 and 17, a reflective exposure mask MSK2 as a modification example of the reflective exposure mask MSK1 of the first and second embodiments is illustrated. FIG. 16 is a cross-sectional view viewed in a direction of the arrow along the line A2-A2 in a plan view illustrated in FIG. 17. A configuration of the reflective exposure mask MSK2 has the same configuration as the reflective exposure mask MSK1 described with reference to FIG. 1 except for the differences as follows in specifications of a specifications of a light-shielding band SD2 outside the pattern region RP1. Therefore, the same goes to the effects to be obtained in the same configuration, and repetitive descriptions thereof will be omitted.

The reflective exposure mask MSK2 illustrated in FIGS. 16 and 17 is the same as the reflective exposure mask MSK1 that the multilayer reflecting film ML1 and the absorber AB1 in the region outside the pattern region RP1 are removed so that the light-shielding band SD2 is provided. In the reflective exposure mask MSK2, the light-shielding band SD2 is formed by removing the multilayer reflecting film ML1 and the absorber AB1 until an outer periphery of the mask substrate SUB1. In this manner, a width of the light-shielding band SD2 is increased, and a region in which the masking blade is stopped can be wide in the step described above with reference to FIG. 14. In other words, an operating range of the masking blade MB1 can be wide. Note that, to electrically connect to the low reflectivity conductor film LE1, ₜhe low reflectivity conductor film LE1 is directly connected in the other region than the pattern region RP1.

However, in view of a method of manufacturing a mask, the reflective exposure mask MSK1 of FIG. 1 including the light-shielding band SD1 having a narrower width than the light-shielding band SD2 of the reflective exposure mask MSK2 is more preferable. The reason is that, as described with reference to FIGS. 8 and 9 described above, to form the light-shielding band SD1, the photoresist film 5 (or electron beam resist film) is necessary to be formed as an etching mask to remove the multilayer reflecting film ML1 etc. at a portion to be the light-shielding band SD1. Also, to expose the portion to be the light-shielding band SD1 from the photoresist film 5 (or electron beam resist film), the photoresist film 5 (or electron beam resist film) is patterned by a laser patterning (or an electron beam patterning). Here, when a pattern is transferred on a surface of the photoresist film 5 (or an electron beam resist film) by, for example, laser (or electron beam), the wider the patterning area is, the lower the throughput is. From this point of view, the reflective exposure mask MSK1 in which the light-shielding band SD1 is formed by removing a part of the multilayer reflecting film ML1 in the other region than the pattern region RP1 as illustrated in FIG. 1 is more preferable.

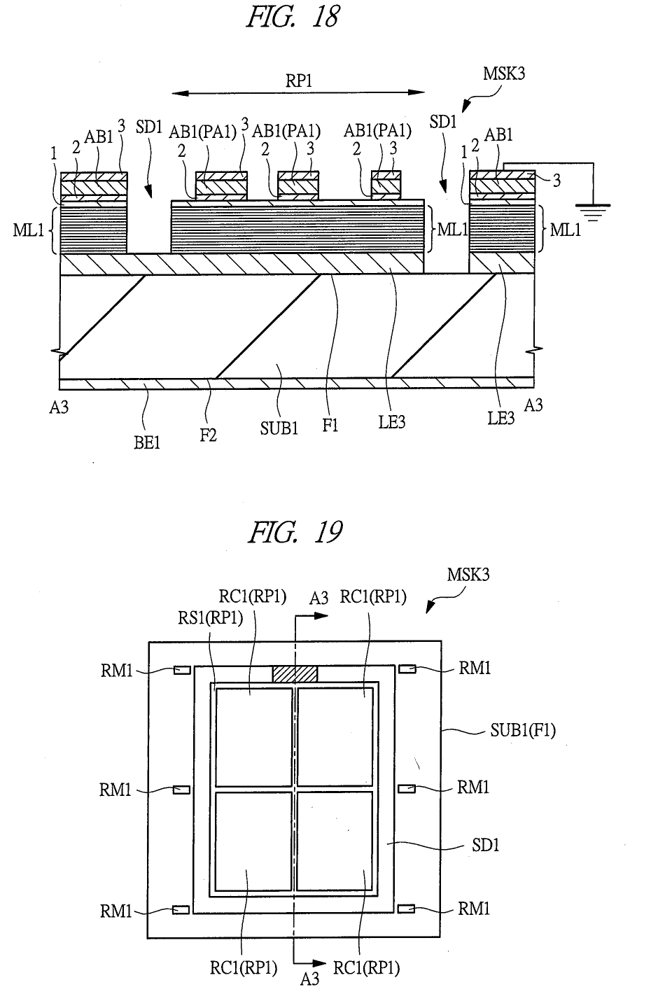

Further, FIGS. 18 and 19 illustrate a reflective exposure mask MSK3 as a modification example of the reflective exposure mask MSK1 of the first and second embodiments. FIG. 18 is a cross-sectional view viewed in a direction of the arrow along the line A3-A3 in a plan view of FIG. 19. A configuration of the reflective exposure mask MSK3 is the same as that of the reflective exposure mask MSK1 described above with reference to FIG. 1 except for the differences as follows in specifications of a low-reflectivity conductor film LE3. Therefore, the same goes to the effects to be obtained by the same configuration, and repetitive descriptions thereof will be omitted.

In the reflective exposure mask MSK3 illustrated in FIGS. 18 and 19, the low reflectivity conductor film LE3 is arranged at a part of a bottom portion of the light-shielding band SD1, and the mask substrate SUB1 under the low reflectivity conductor film LE3 is exposed in the other part. As described above, the low reflectivity conductor film LE3 is provided for an electric conduction from another region via the low reflectivity conductor film LE3 not to put the multilayer reflecting film ML1 of the pattern region RP1 in a floating state. Therefore, the low reflectivity conductor film LE3 is not necessarily disposed to the entire of the bottom portion of the light-shielding band SD1, and it is sufficient when the low reflectivity conductor film LE3 is partly disposed in the other region than the pattern region RP1. The reason is that the multilayer reflecting film ML1 of the pattern region RP1 can be in a non-floating state when even a part of the low reflectivity conductor film LE3 is disposed in the other region than the pattern region RP1. Note that the mask substrate SUB1 exposed instead is also formed of the same low reflectivity material as described above and sufficiently thick, and thus a desired reflectivity as the light-shielding band SD1 can be achieved. That is, also in the configuration described here, a structure preventing charging of the pattern region RP1 can be achieved with satisfying conditions in view of the structure as the light-shielding band SD1.

For example, when the low reflectivity conductor film LE3 cannot be thick from a reason in view of the structure and a reflectivity is not low enough for achieving functions as the light-shielding band SD1, it is effective to make the structure in which the low reflectivity conductor film LE3 at a part of the bottom of the light-shielding band SD1 is left and the low reflectivity conductor film LE3 in the other part is removed.

In addition, for example, strain of the mask substrate SUB1 due to stress of the low reflectivity conductor film LE3 etc. is concerned, it is also effective to make the structure in which the low reflectivity conductor film LE3 at a part of the bottom of the light-shielding band SD1 is left and the low reflectivity conductor film LE3 in the other part is removed.

However, in view of a method of manufacturing a mask, the reflective exposure mask MSK1 in FIG. 1 in which the low reflectivity conductor film LE1 is disposed on the entire surface of the bottom portion of the light-shielding band SD1 is more preferable. The reason is, as illustrated in FIGS. 18 and 19, when the structure, in which a part of the low reflectivity conductor film LE3 at the bottom portion of the light-shielding band SD1 is removed, is used, it is necessary to add a photolithography process and an etching process especially for removing the part of the low reflectivity conductor film LE3. From this point of view, for the low reflectivity conductor film LE1, it is more preferable to use the reflective exposure mask MSK1 covering the entire of the main surface F1 of the mask substrate SUB1 and not subjected to a processing.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be widely used in a manufacturing field of a semiconductor device, particularly, a manufacturing field of a semiconductor device using a reflective exposure mask using EUV light having a wavelength near 13.5 nm.

What is claimed is:

1. A reflective exposure mask reflecting extreme ultraviolet rays and supplying the same as exposure light, the reflective exposure mask comprising:
a mask substrate;
a conductor film formed to cover an entire surface of a main surface of the mask substrate;
a reflecting film disposed on the mask substrate via the conductor film and in contact with the conductor film;
a light-shielding band which is a portion where the reflecting film is removed in a groove-like shape; and
an absorber disposed on the reflecting film,
wherein a reflectivity to the extreme ultraviolet rays of the absorber is lower than a reflectivity to the extreme ultraviolet rays of the reflecting film,
wherein the absorber in a pattern region on the mask substrate includes an absorber pattern having a portion covering the reflecting film and a portion not covering the reflecting film to expose the reflecting film,
wherein the pattern region is arranged at a position inside an outer periphery of the mask substrate and not in contact with the outer periphery of the mask substrate when viewing the main surface of the mask substrate in a plane,
wherein the light-shielding band is a portion in which the reflecting film is removed in a groove-like shape outside an outer periphery of the pattern region and surrounding the pattern region in a state in contact with the outer periphery of the pattern region when viewing the main surface of the mask substrate in a plane,
wherein the conductor film is exposed at a bottom portion of the light-shielding band, and
wherein a reflectivity to the extreme ultraviolet rays of the light-shielding band is lower than reflectivities to the extreme ultraviolet rays of the reflecting film and the absorber.

2. The reflective exposure mask according to claim 1,
wherein the conductor film is formed of a same material as the absorber.

3. The reflective exposure mask according to claim 2,
wherein a thickness of the conductor film is larger than a thickness of the absorber.

4. The reflective exposure mask according to claim 3,
wherein the reflecting film is a multilayer film formed by alternately stacking silicon layers and molybdenum layers.

5. The reflective exposure mask according to claim 4,
wherein a back-surface conductor film is formed of a conductor film mainly containing chrome or chrome nitride and formed to cover a back surface of the mask substrate positioned on an opposite side of the main surface of the mask substrate in a thickness direction of the mask substrate.

6. A method of manufacturing a reflective exposure mask which reflects extreme ultraviolet rays and supplies the same as exposure light, the method comprising the steps of:
(a) forming a mask substrate;
(b) forming a conductor film covering an entire surface of a main surface of the mask substrate;
(c) forming a reflective exposure mask blank by forming a reflecting film and an absorber film in sequence covering the conductor film;
(d) forming an absorber pattern including a part covering the reflecting film and a part not covering the reflecting film to expose the reflecting film by processing the absorber film in a pattern region of the reflective exposure mask blank; and
(e) forming a light-shielding band by removing the reflecting film in a groove-like shape outside an outer periphery of the pattern region and surrounding the pattern region in a state in contact with the outer periphery of the pattern region when viewing a main surface of the reflective exposure mask blank in a plane,
wherein, in the step (b) , the conductor film is formed of a material having a reflectivity to the extreme ultraviolet rays lower than reflectivities of the reflecting film and the absorber film,
wherein, in the step (c) , the absorber film is formed of a material having a reflectivity to the extreme ultraviolet rays lower than the reflectivity of the reflecting film,
wherein, in the step (d) , the absorber pattern is formed by processing the absorber film in the pattern region at a position inside an outer periphery of the reflective exposure mask blank and not in contact with the outer periphery of the reflective exposure mask blank when viewing the main surface of the reflective exposure mask blank in a plane, and
wherein, in the step (e) , the light-shielding band is formed by removing the reflecting film without removing the conductor film formed under the reflecting film so that the conductor film is exposed at a bottom portion of the light-shielding band.

7. The method of manufacturing a reflective exposure mask according to claim 6,
wherein, in the steps (b) and (c), the conductor film and the absorber film are formed of a same material.

8. The method of manufacturing a reflective exposure mask according to claim 7,
wherein, in the steps (b) and (c) , the conductor film and the absorber film are formed so that the conductor film is thicker than the absorber film.

9. The method of manufacturing a reflective exposure mask according to claim 8,
wherein, in the step (c), the reflecting film is formed of a multilayer film formed by alternately stacking silicon layers and molybdenum layers.

10. The method of manufacturing a reflective exposure mask according to claim 9, the method further comprising the step of
(f) forming a back-surface conductor film covering a back surface of the mask substrate positioned on an opposite side of the main surface of the mask substrate in a thickness direction of the mask substrate,
wherein, in the step (f), a conductor film mainly containing chrome or chrome nitride is formed as the back-surface conductor film.

11. A method of manufacturing a semiconductor device comprising the steps of:
(a) preparing a reflective exposure mask;
(b) forming an EUV resist film on a semiconductor wafer;
(c) irradiating extreme ultraviolet rays to a pattern region of the reflective exposure mask to obtain reflected light;
(d) exposing the EUV resist film in a first region on the semiconductor wafer by the reflected light; and
(e) exposing the EUV resist film in a second region on the semiconductor wafer, the second region being adjacent to the first region or being adjacent to the first region with being overlapped by only a scribe region, by steps same as the steps from (c) to (d),
wherein, in the step (a), a reflective exposure mask is prepared, the reflective exposure mask including:
a mask substrate;
a conductor film formed to cover an entire surface of a main surface of the mask substrate;
a reflecting film disposed on the mask substrate via the conductor film and in contact with the conductor film;
a light-shielding band which is a portion where the reflecting film is removed in a groove-like shape; and
an absorber disposed on the reflecting film,
wherein a reflectivity to the extreme ultraviolet rays of the absorber is lower than a reflectivity to the extreme ultraviolet rays of the reflecting film,
wherein the absorber in a pattern region on the mask substrate includes an absorber pattern having a portion covering the reflecting film and a portion not covering the reflecting film to expose the reflecting film,
wherein the pattern region is arranged at a position inside an outer periphery of the mask substrate and not in contact with the outer periphery of the mask substrate when viewing the main surface of the mask substrate in a plane,
wherein the light-shielding band is a portion in which the reflecting film is removed in a groove-like shape outside an outer periphery of the pattern region and surrounding the pattern region in a state in contact with the outer periphery of the pattern region when viewing the main surface of the mask substrate in a plane,
wherein the conductor film is exposed at a bottom portion of the light-shielding band, and
wherein a reflectivity to the extreme ultraviolet rays of the light-shielding band is lower than reflectivities to the extreme ultraviolet rays of the reflecting film and the absorber, and
wherein, the step (c) further includes the steps of:
(c1) disposing a masking blade which does not pass the extreme ultraviolet rays overlapping a region other than the pattern region in a plane in the reflective exposure mask; and
(c2) irradiating the extreme ultraviolet rays to the reflective exposure mask from the side the masking blade is disposed to obtain the reflected light from the pattern region not covered by the masking blade,
wherein, in the step (c1) , the masking blade is arranged so that an edge portion of the masking blade is stopped at a position overlapped with the light-shielding band in a plane.

12. The method of manufacturing a semiconductor device according to claim 11,
wherein, in the step (a) , the reflective exposure mask in which a back-surface conductor film is formed is prepared, the back-surface conductor film being formed of a conductor film mainly containing chrome of chrome nitride covering a back surface of the mask substrate positioned on an opposite side of the main surface of the mask substrate in a thickness direction of the mask substrate, and
wherein, during the steps from (c) to (e), the reflective exposure mask is fixed by electrostatically chucking the back-surface conductor film formed to the back surface of the mask substrate.

13. The method of manufacturing a semiconductor device according to claim 12,
wherein, during the steps from (c) to (e) , the conductor film formed to the main surface of the mask substrate is set at a ground potential.

14. The method of manufacturing a semiconductor device according to claim 13,
wherein, in the step (a) , the reflective exposure mask in which the conductor film and the absorber are formed of a same material is prepared.

15. The method of manufacturing a semiconductor device according to claim 14,
wherein, in the step (a) , the reflective exposure mask in which a thickness of the conductor film is larger than a thickness of the absorber is prepared.

16. The method of manufacturing a semiconductor device according to claim 15,
wherein, in the step (a) , the reflective exposure mask in which the reflecting film is formed of a multilayer film formed by alternately stacking silicon layers and molybdenum layers is prepared.
